(19) United States
(12) Patent Application Publication
(10) Pub. No.: US 2020/0377993 A1
(43) Pub. Date: Dec. 3, 2020

(54) Sputtering Target And Method For Preparing Thereof

(71) Applicant: JX Nippon Mining & Metals Corporation, Chiyoda-ku, Tokyo (JP)

(72) Inventor: Jun Kajiyama, Ibaraki (JP)

(21) Appl. No.: 16/082,601

(22) PCT Filed: Oct. 31, 2017
(86) PCT No.: PCT/JP2017/039402

§ 371 Date: Sep. 6, 2018

(30) Foreign Application Priority Data
Mar. 31, 2017 (JP) 2017-072038

(51) Int. Cl. C23C 14/34; C01G 15/00

(52) U.S. Cl. CPC C23C 14/3414; H01L 21/02565; C01G 15/006

(57) ABSTRACT

[Problem to be solved] To provide an IGZO sputtering target occurring less arcing

[Means for solving the problem] An IGZO sputtering target comprising In, Ga, Zn, and O,
wherein atom ratios for In, Ga, and Zn are:
   0.30≤In/(In+Ga+Zn)≤0.36,
   0.30≤Ga/(In+Ga+Zn)≤0.36 and
   0.30≤Zn/(In+Ga+Zn)≤0.36,
wherein a relative density is at least 96%,
wherein average crystal grain size in surface of the sputtering target is 30.0 μm or less, and
wherein difference of the grain size in surface of the sputtering target is 20% or less (1.0≤Dmax/Dmin≤1.2).

### FIELD OF INVENTION

The present invention is related to a sputtering target and a method for preparing thereof, in particular, to an IGZO sputtering target and a method for preparing thereof.

### TECHNICAL BACKGROUND

Conventionally, IGZO film has been expected to be applied to film transistor, especially to the field of display. This IGZO film can be formed mainly by sputtering.

In forming a film by sputtering, occurrence of particles results in an undesirable pattern. The most frequent cause of the occurrence of particles is arcing, which occurs during sputtering. Especially, when arcing occurs on surface of a target, materials of the target around positions where arcing occurs are released in a cluster state (a bulk state) from the target. Then, this cluster of the target attaches to substrate.

In view of an issue of accuracy for a recent display, a level required for fewer particles in sputtering has been getting stricter than ever. In order to solve such an issue in sputtering, those skilled in the art have tried increasing a density of a target, or controlling crystal grain to obtain a high-strength target.

JP Patent Application Publication No. 2014-125422 teaches to control the ratio of diffraction intensity for an angle of incidence (two theta) for the purpose of improving uniformity of the property of IGZO film and avoiding a target from being broken in preparing the target or in sputtering.

### LIST OF PRIOR ARTS

### Patent Document

[Patent Document 1] JP Patent Application Publication No. 2014-125422

### SUMMARY OF INVENTION

### Problem to be Solved

In recent years, decrease of arcing has been strongly desired for the purpose of improving quality of display and applying oxide semiconductors to new devices. In view of this situation, an object of the present invention is to provide an IGZO sputtering target, in which arcing occurs less frequently than those according to the conventional technique.

### Means for Solving the Problem

Regarding to crystal structures of a sintered body for an IGZO target (just after sintering), the target generally has a deteriorated layer on its surface. In the deteriorated layer, there is a lot of trans-granular crack. Then, surface of a target is usually ground with a sufficient amount such that the deteriorated layer in the surface is removed.

However, even if grinding sufficiently such that a deteriorated layer is removed, arcing still occasionally occurs. As a result of investigation by the present inventor, the following things were found. Specifically, on the surface (sputtering side) of a target just after grinding, deviation of crystal grain size was found, resulting in arcing. Furthermore, as a result of a detailed investigation of its cause, it was found to be caused from an occurrence of deflection in the shape of a sintered body just after sintering. More specifically, a deflected sintered body is usually ground for the purpose of processing to obtain a flat target as a product. As shown in FIG. 2, for the purpose of flat-grinding, an amount of grinding differs depending on its position to be ground. For example, comparing between the center portion and the edge portions of the same surface, the amounts of grinding differs from each other. As a result, each of portions on the surface of the target is exposed, which had a different distance from the surface of the pre-ground sintered body.

Because of the difference of the distance, portions being varied in their influences of temperature by heat treatment, that is, portions being varied in their crystal grain sizes are exposed on the same surface.

As a result of the inventor's intensive research, it was found that in sintering a shaped body, maintaining under certain temperature before reaching a sintering temperature decreases an amount of material's deflection. Furthermore, it was found to be possible to achieve uniformity of crystal grain size in surface exposed after grinding.

Based on the above, the present invention includes the following inventions.

### (Invention 1)

An IGZO sputtering target comprising In, Ga, Zn, and O,
wherein atom ratios for In, Ga, and Zn are:
   0.30≤In/(In+Ga+Zn)≤0.36,
   0.30≤Ga/(In+Ga+Zn)≤0.36 and
   0.30≤Zn/(In+Ga+Zn)≤0.36,
wherein a relative density is at least 96%
wherein an average crystal grain size in surface of the sputtering target is 30.0 μm or less, and
wherein difference of the grain size in the surface of the sputtering target is 20% or less (1.0 Dmax/Dmin 1.2).

### (Invention 2)

The IGZO sputtering target of Invention 1,
wherein transverse intensity is from 40 to 100 MPa, and
wherein difference of the transverse intensity is 20% or less (1.0≤Smax/Smin≤1.2).

### (Invention 3)

A method for preparing an IGZO sputtering target, comprising:
   sintering a shaped body having elemental components according to Invention 1 or 2 under 1300-1500° C. for 5-24 hours; and
   grinding a sintered body;
the sintering including treating the shaped body under 800-1000° C. degree for 0.5-3 hours,
wherein an amount of deflection for the sintered body after the sintering is 2.0 mm or less,
the grinding including an additional grinding with an amount of 0.5 mm or more after removing deflection.

### Effect of Invention

In one aspect, the invention includes a target in which difference of the grain size in the surface of the sputtering target is 20% or less. Thereby, arcing etc. in sputtering can be decreased. Further, in another aspect, the invention includes a target in which difference of the transverse intensity in the sputtering target is 20% or less. Thereby, an occurrence of breakage can be effectively decreased.

### BRIEF DESCRIPTION OF DRAWINGS

FIG. 1 shows a method of sampling for analyzing grain size and strength.

FIG. 2 shows how to evaluate an amount of deflection and an amount of grinding for a sintered body.

### DETAILED DESCRIPTION OF THE EMBODIMENT

Now, detailed descriptions of embodiments according to the invention are described. The descriptions hereinafter are aiming for promoting understanding of the invention. In other words, the descriptions hereinafter are not intended to limit the scope of the invention.

### 1. Property of Targets

### (1) Shape

In one embodiment of the invention, the shape of a sputtering target is flat plate. In another embodiment of the invention, the shape of a sputtering target is rectangle-shaped flat plate.

### (2) Chemical Component

In one embodiment of the invention, a sputtering target is an IGZO sputtering target comprising In, Ga, Zn and O.

In another embodiment of the invention, the IGZO sputtering target may comprise In, Ga and Zn with the following atom ratios:
0.30≤In/(In+Ga+Zn)≤0.36;
0.30≤Ga/(In+Ga+Zn)≤0.36; and
0.30≤Zn/(In+Ga+Zn)≤0.36.

More preferably, the IGZO sputtering target may comprise In, Ga and Zn with the following atom ratios:
0.32≤In/(In+Ga+Zn)≤0.34;
0.32≤Ga/(In+Ga+Zn)≤0.34; and
0.32≤Zn/(In+Ga+Zn)≤0.34.

In addition to the above described chemical elements, the remainder may comprise, for example, Sn and/or Zr. The amounts of each of the chemical elements may be, for example, 1000 ppm by mass or less respectively, preferably 500 ppm by mass or less respectively. Typically, the amount of Sn may be 400 ppm by mass or less, and/or the amount of Zr may be 200 ppm by mass or less. The lower limits for them may be, for example, 0 ppm by mass or more respectively, but is not limited thereto. Typically, the lower limit of Zr may be 100 ppm by mass or more and/or the lower limit of Sn may be 300 ppm by mass or more. Incidentally, types of chemical elements and their amounts

constituting a sputtering target can be determined by X-ray Fluorescence Analysis (XRF) etc. Also, chemical elements other than In, Ga and Zn can be determined by emission spectrochemical analysis (ICP).

### (3) Crystal Structure

In one embodiment of the invention, an IGZO sputtering target has homologous crystal structure. The homologous crystal structure described herein in case of an oxide comprising In, Ga and Zn means layered-structure with the unit of hexagonal crystal represented by InGaO₃(ZnO)ₘ (m being natural number from 1 to 20). In another embodiment of the invention, an IGZO sputtering target has predominantly the homologous crystal structure represented by InGaZnO₄(InGaO₃(ZnO)m, m=1). For example, an IGZO sputtering target has homologous crystal structure with the ratio of 80% or more, preferably, 85% or more.

Incidentally, whether the presence or absence for homologous crystal structure can be determined by detecting XRD peak. In one embodiment of the invention, when analyzing an IGZO sputtering target by XRD, peak corresponding to InGaZnO₄ may be detected (although there may be peak shift of ±1° due to such as distortion). In another embodiment of the invention, when analyzing an IGZO sputtering target by XRD, the ratio of the peak intensity not corresponding to InGaZnO₄ phase (not corresponding even if considering peak shift due to such as distortion) to the ratio of the peak intensity corresponding to InGaZnO₄ phase is 20% or less (preferably 15% or less).

Conditions for measuring by XRD described above may be, for example, as follows.
X-ray diffractometer: Automated multipurpose X-ray diffractometer SmartLab, manufactured by RIGAKU (X-ray source:Cu);
Goniometer: Ultima IV
X-ray tube voltage: 40 kV
X-ray tube current: 30°/min
Step size:0.02°

Background reduction: Each of peak intensities can be calculated by removing background from data obtained from XRD. A method for removing background may be according to a Sonneveld-Visser method.

By constituting materials by the atomic ratios of In Ga and Zn as described above, and by sintering under temperature conditions as described hereinafter, an IGZO sputtering target having homologous crystal structure can be prepared.

### (4) Grain Size

In one embodiment of the invention, crystal grain size of an IGZO sputtering target is 30.0 μm or less, more preferably, 25.0 μm or less. These ranges can result in appropriate decrease of particles or crack etc. The lower limit is typically 5.0 μm or more, or, 7.0 μm or more, but is not limited thereto.

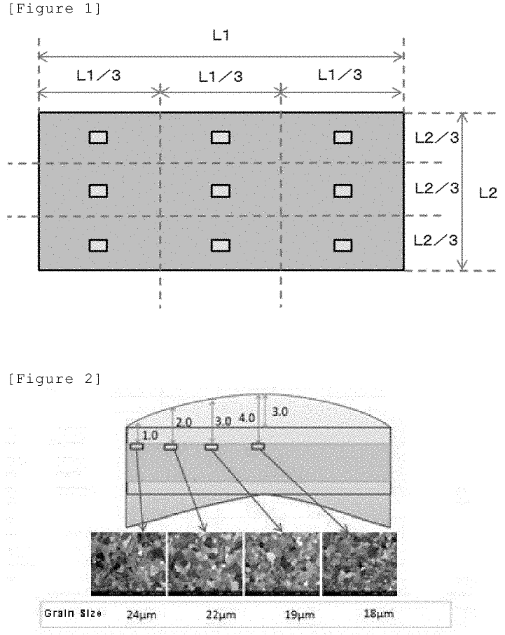

Incidentally, the crystal grain size described herein is defined by the following procedure. As shown FIG. 1, a target is divided into nine parts (3 equal parts with vertical wise and 3 equal parts with horizontal wise). Samples are respectively obtained by cutting central portions out of the nine parts. Each of the samples is processed by mirror-polishing and etching (by 2 mm) for the both sides of the samples (i.e., the side for sputtering, and the opposite side thereof (which is attached to a backing plate)). After then, the structures are observed by FE-EPMA. Next, on pictures of the structures that has been observed and saved, a straight line is drawn until the line crosses over 200 grains (N=200). Using the number of grains existing on the line (N≥200), and using the whole length of the line (L), L/N is calculated for the observed ranges, that is, each of grain size for the side for sputtering and the opposite side thereof of the parts is calculated respectively. After calculating the grain sizes for the side for sputtering and the opposite side thereof (18 sections), the grain size values in the 9 sections on the side for sputtering are defined as D1-D9, and the grain size values in the 9 sections on the opposite side thereof are defined as D10-D18. Among D1-18, the maximum value and the minimum value are picked up for calculating difference of the grain size. Further, an average grain size for a target is derived from the value Lsum/Nsum, the Lsum being the sum of the values L for each samples, and the Nsum being the sum of the values N for each samples.

In one embodiment of the invention, difference of crystal grain size in an IGZO sputtering target is 20% or less, preferably 15% or less. Incidentally, difference of crystal grain size described herein can be represented by the ratio of the maximum value (Dmax) and the minimum value (Dmin) among the crystal grain sizes D1-D18 as described above, that is (Dmax/Dmin). The lower limit may be typically, 0% or more, 1% or more, or 3% or more, but is not limited thereto.

### (5) Relative Density

In one embodiment of the invention, relative density for an IGZO sputtering target is 96% or more, preferably, 96.3% or more. The relative density of 96% or more results in further decrease of arcing. The upper limit may be typically 100% or less, 99% or less, 98% or less, or 97% or less, but is not limited thereto.

Incidentally, a relative density described herein is calculated as being the ratio of (measured density/theoretical density) X 100 (%). The term “measured density” described herein is a value measured by Archimedes method. The “theoretical density” can be derived by analyzing values for each chemical element (the ratio of % by weight) and then convert into the values of each oxide such as In₂O₃, Ga₂O₃, ZnO. The theoretical densities for each oxide are as follows: In₂O₃: 7.18g/cm³, Ga₂O₃: 6.44g/cm³, ZnO: 5.61g/cm³.

### (6) Transverse Intensity

In one embodiment of the invention, the transverse intensity of an IGZO sputtering target is from 40 to 100 MPa, more preferably, from 70 to 100 MPa. The transverse intensity is measured by, as similar to the above measurement of the crystal grain size, dividing a material into 9 parts to be measured. More specifically, samples are obtained by cutting central portions out of the 9 parts (3 equal parts with vertical wise and 3 equal parts with horizontal wise) such that the samples have certain dimensions as described hereinafter. Then, the samples that have been cut out of the 9 parts are analyzed to measure the transverse intensity, which are defined as being S1-S9 respectively. The average for S1-S9 is calculated and defined as being the transverse intensity for an IGZO sputtering target.

The transverse intensity can be measured according to JIS (Japanese Industrial Standards) “JIS R 1601”. This JIS defines thickness of sample as being 3 mm. For the purpose of processing to achieve the thickness, both of the sputtering side and the opposite side thereof are ground with the same amount. Then, a material is divided into nine parts, followed by cutting central portions out of each of the nine parts such that the samples having been cut are rectangle with the dimensions of 4×40 mm. Details are as follows.

(Conditions for measuring transverse intensity)
Method for testing: three point bending test
Distance between supporting points: 30 mm
Size of samples: 3×4×40 mm
Head speed: 0.5 mm/min

In one embodiment of the invention, difference of transverse intensity for an IGZO sputtering target may be 20% or less, more preferably 16% or less. Even if a target has a high transverse intensity as a whole, existence of a portion where transverse intensity is small may cause breakage from the portion. However, an IGZO sputtering target according to the invention has difference of transverse intensity as being 20% or less, thereby being able to effectively decrease breakage. Incidentally, the “difference of transverse intensity” described herein can be represented by the ratio (Smax/Smin), the Smax is the maximum value among the above transverse intensity S1-S9, and the Smin is the minimum value among the above transverse intensity S1-S9. The lower limit may be typically 0% or more, 1% or more, or 3% or more, but is not limited thereto.

### 4. Method for Preparing a Target

### (1) Powder

Certain types of powder respectively containing In, Ga, and Zn may be used. More specifically, powder of In compound, powder of Ga compound, and powder of Zn compound may be used. Alternatively, a type of powder containing the combination of these chemical elements may be used. Examples of In compound include indium oxide, indium hydroxide etc. Examples of Ga compound include gallium oxide, gallium nitrate etc. Examples of Zn compound include zinc oxide, zinc hydroxide etc. The amounts of formulation may be such that the above described atomic ratios for In, Ga and Zn are achieved.

### (2) Mixing and Pulverization

Next, these powder materials are pulverized and mixed. Mixing and Pulverization for the powder materials may be according to dry methods or wet methods. The dry methods include the ones using balls or beads such as zirconia, alumina, and nylon resin. Meanwhile, the wet methods include media-agitating mill using the balls or beads as described above. Furthermore, the wet methods include media-less type such as container rotating type, machine-agitating type, and air-blowing type. In general, wet methods are more advantageous than dry methods in view of the ability of mixing and pulverization. Thus, wet methods are more preferable for mixing.

Regarding to a grain size after pulverization, though it is not intended to limit the invention, the smaller size, the higher relative density, which is thus preferable. Moreover, if pulverization is insufficient, uniformity for each component may occur in a prepared target such that high-resistance region and low-resistance region may co-exist. Thereby, anomalous electric discharge such as arcing may be caused by, for example, charge at high-resistance region in forming film by sputtering. Thus, sufficient mixing and pulverization are required.

### (3) Shaping

Next, the mixed powder is filled in a mold, and subject to uniaxial pressing under the following conditions; specifically, a surface pressure of 400 to 1000 kgf/cm² and a holding time of 1 to 3 minutes to obtain a shaped body. When the surface pressure is less than 400 kgf/cm², it is not possible to obtain a shaped-body having a sufficient density. Moreover, the surface pressure more than 1000 kgf/cm² is not particularly required for producing. In other words, even if excessive surface pressure is applied, the density of a shaped body hardly increases beyond a certain level. Furthermore, a density distribution tends to become generated in shaped body in principle when being subject to uniaxial pressing more than 1000 kgf/cm², and causes deformation and cracks during sintering.

Next, this shaped body is subject to double vacuum packing in vinyl, and CIP (cold isostatic pressing) under the following conditions; specifically, a pressure of 1500 to 4000 kgf/cm², and a holding time of 1 to 3 minutes. When the pressure is less than 1500 kgf/cm², it is not possible to obtain a sufficient effect of CIP. Meanwhile, even if pressure of 4000 kgf/cm² or more is applied, the density of the shaped body hardly increases beyond a certain level, and therefore, a surface pressure of 4000 kgf/cm² or more is not particularly required for production. Although the size of the shaped body is not limited to certain size, too large thickness leads to difficulty in obtaining a sintered body with high relative density. Thus, thickness of a shaped body is preferably adjusted such that the thickness of the shaped body is 15 mm or less.

### (4) Sintering

The above shaped body may be sintered under appropriate sintering temperature to obtain a sintered body. It is preferable to hold under certain conditions prior to reaching sintering temperature. Regarding to an IGZO sintered body, various types of phases grow and diminish depending on temperature. For example, the phases of I₂O₃ and ZnGa₂O₄ etc. tend to decrease when temperature increases to 800° C. or more. Meanwhile, the phase of InGaZnO₄ tends to rapidly grow when temperature increases beyond 1000° C. Thus, not increasing to sintering temperature without holding, but increasing temperature with transiently holding in the range of 800-1000° C. makes it possible to inhibit phenomenon which is the cause of deflecting (i.e., phenomenon in which the difference of degree for growth of IGZO phase inside of a sintered body occurs). Then, it is possible to sinter under the conditions that the difference of degree for growth of IGZO phase decreases. For these reasons, the range of temperature for the holding is preferably 800-1000° C. (more preferably 850-1000° C., yet more preferably 880-920° C.). The time for the holding is preferably 0.5 hour or more, more preferably 1 hour or more. The upper limit for the holding time is preferably 3 hours or less. This is because if the holding time is more than 3 hours, the growth of an IGZO phase occurs in whole of a sintered body, and pores become hard to be removed from a sintered body, resulting in low relative density and low transverse intensity etc. in a target.

For example, during the above holding time ranges, a shaped body may be treated under fixed temperature. Alternatively, during the above holding time ranges, the speed of increasing temperature may be adjusted to be small (for example, 0.1-0.3° C./min) to take certain time until reaching the above sintering temperature. The above holding prior to reaching sintering temperature makes it possible to inhibit the occurrence of deflection of a sintered body. Such a treatment is effective for inhibiting the occurrence of deflection of a sintered body especially in the case of the component as described in the above item “(2) Chemical component” in the section “1. Property of targets” and/or in the case of the structure as described in the item “(3) Crystal structure” in the section “1. Property of targets”.

Next, a shaped body is sintered under an air atmosphere or an oxidative atmosphere at the temperature 1300-1500° C. (preferably 1350-1450° C.) for 5-24 hours (preferably 10-22 hours, more preferably 15-21 hours) to obtain a sintered body. If the temperature for sintering is less than 1300° C., it is hard to achieve sufficient density for a sintered body. Further, it is hard to obtain a sufficient amount of the crystal phase InGaZnO₄. If the temperature for sintering is more than 1500° C., a crystal grain size may become too large in a sintered body, resulting in low mechanical strength of the sintered body. Moreover, if the time is less than 5 hours, it is hard to obtain a sintered body with sufficient density. If the time is more than 24 hours, it would not be preferable in view of cost of production.

As for the process of shaping and sintering, instead of the above described method, HP(Hot Press) and/or HIP(Hot Isostatic Pressing) can be available. A sintered body obtained through the above process may be subjected to mechanical processing such as grinding and polishing to obtain certain shape suitable for a target and then to obtain a sputtering target.

The amount of deflecting for a sintered body is 2.0 mm or less, more preferably 1.5 mm or less. If the amount is 2.0 mm or less, the difference of crystal grain size in surface of a target after grinding may be decreased to certain value or less. Further, occurrence of arcing may be decreased. The lower limit is 0 mm or more, 0.5 mm or more, or 0.8 mm or more, but is not limited thereto.

Incidentally, an amount of the deflection described herein means the value of the difference of height(z-axis) between the highest point and the lowest point which are obtained by measuring a sintered body after sintering (and prior to mechanical processing) with use of Displacement Sensor (measuring element manufactured by KEYENCE, LK-085).

### (5) Grinding

After obtaining a sintered body, grinding is performed for the purpose of processing it to flat shape and removing a deteriorated layer. Both sides of the sintered body may be ground to obtain a target with the shape of flat plate. Thus, it is required to grind at least until flat shape is achieved. For example, if an amount of deflection is 2.0 mm or more, it is required to grind with an amount of 2.0 mm or more. More preferably, after grinding until deflection is removed, further grinding may be performed with an amount of +0.5 mm or more (in other words, an amount of additional grinding after obtaining flat shape is 0.5 mm or more, more preferably, 0.8 mm or more). Thereby, difference of crystal grain size in surface of a target after grinding becomes smaller. Also, thereby, a deteriorated layer may be removed, which still partially remains on surface even after grinding until deflection is removed. Incidentally, the status where deflection is removed may mean not only the status where an amount of deflection is 0 mm, but also may mean the status where an amount of deflection is 0.1 mm or less. Regarding to the upper limit for an amount of grinding, a maximum amount of grinding (which is the sum of an amount of grinding until deflection is removed and an amount of additional grinding)is preferably 3.0 mm or less because yield would decrease otherwise. Regarding to the lower limit for an amount of grinding, since a typical amount of deflection is 0.5 mm or more and a preferable amount of additional grinding is 0.5 mm or more, a maximum amount of grinding (which is the sum of an amount of grinding until deflection is removed and an amount of additional grinding) is preferably 1.0 mm or more.

An IGZO sputtering target that the present invention aims for may be obtained via the above process.

### 5. Usability of a Target

In one embodiment of the invention, an IGZO sputtering target may be used to form film via a general sputtering method (e.g., DC sputtering etc.). In one embodiment of the invention, an IGZO sputtering target according to the invention has less deflection and thus an amount of grinding until flat shape is obtained is less than those prepared according to conventional technique, resulting in decrease of material loss. Furthermore, since an amount of deflection is small, uniformity of surface for sputtering can be achieved. Thus, arcing can be decreased. Moreover, since a material as a whole has strength more than certain level and the difference of the strength is small, breakage or crack occurs less frequently.

### EXAMPLES

### (1) Conditions for Each of Tests

Each of tests was preformed according to the following conditions.

(1-1) Analysis for a target

Analysis for chemical elements (In, Ga, and Zn) was performed via X-ray Fluorescence Analysis (XRF).

### (1-2) Measurement for Grain Size

Grain size was evaluated via a method according to the item “(4) Grain size” in the section “1. Property of targets”.

### (1-3) Measurement for Strength

Strength was evaluated via a method according to the item “(6) Transverse intensity” in the section “1. Property of targets”.

### (1-4) Measurement for an Amount of Deflection

The value of the difference of height(z-axis) between the highest point and the lowest point which are obtained by measuring a sintered body after sintering (but prior to mechanical processing) with use of Displacement Sensor (measuring element manufactured by KEYENCE, LK-085) was regarded as an amount of deflection.

### (1-5) Relative Density

Relative density was evaluated according to the item “(5)Relative density” in the section “1. Property of targets”.

### (1-6) Conditions for Sputtering

Using an obtained sintered body, DC sputtering was performed according to the following conditions.
Gas for sputtering: Ar 100%
Gas pressure for sputtering: 0.5 Pa
Electric power introduced: 500 W
Electric energy: 20 kWh
Temperature of substrate: Room temperature

### (2)Working Examples and Comparative Examples

Basic materials consisting of the powder of In₂O₃, the powder of Ga₂O₃ and the powder of ZnO were mixed and pulverized via a wet method such that the ratio for each of the metal elements In:Ga:Zn was approximately 1:1:1, (specifically, such that the atomic ratios as shown in Table 1 were achieved), followed by drying and granularizing via spray drying to obtain material powder. After then, the material powder was introduced into a mold to be subjected to a pressure of 800 kgf/cm² for 1 min to obtain shaped bodies. These shaped bodies were heated in an electric furnace according to the conditions as shown in Table 1 (the speed of increasing temperature was 5° C./min during 300-900° C., and the speed of increasing temperature was 0.5° C. degree/min after increasing beyond 900° C.) and then sintered bodies were obtained (thickness was 10 mm except for the comparative example 5). After then, the sintered bodies were ground by surface grinding machine using grindstones with #80-#400 according to the conditions as shown in Table 1 to obtain sputtering targets (surface finishing of the target was done by grindstone #400)

TABLE 1

| | Condition of test | | | | | | |
|---|---|---|---|---|---|---|---|
| | | | | Conditions of manufacturing/amounts of deflection, | | | |
| | | | | amounts of grinding | | | |
| | | | | | | | amounts of additional |
| | Component (Analyzed values/at %) | | | holding | Sintering temp | amounts of | grinding after |
| | In/ | Ga/ | Zn/ | 900° C. | ° C. | deflection | obtaining flat shape |
| | (In + Ga + Zn) | (In + Ga + Zn) | (In + Ga + Zn) | 1 h | (20 h) | (mm) | (mm) |
| Ex 1 | 33.3 | 33.2 | 33.4 | done | 1370 | 0.9 | 1.0 |
| Ex 2 | 33.3 | 33.2 | 33.4 | done | 1370 | 1.0 | 2.0 |
| Ex 3 | 33.4 | 33.2 | 33.4 | done | 1370 | 1.4 | 1.0 |
| Comp 1 | 33.3 | 33.2 | 33.4 | not done | 1370 | 2.5 | 1.0 |
| Ex 4 | 33.3 | 33.2 | 33.4 | done | 1430 | 1.5 | 1.0 |
| Comp 2 | 33.4 | 33.2 | 33.4 | not done | 1430 | 2.9 | 1.0 |
| Comp 3 | 33.4 | 33.1 | 33.5 | done | 1370 | 1.2 | 0 |
| Comp 4 | 33.4 | 33.1 | 33.5 | done | 1370 | 1.4 | 0.3 |
| Comp 5 | 33.4 | 33.1 | 33.5 | not done | 1370 | 2.9 | 5.0 |

Ex: Working example
Comp: Comparative example

After then, the samples were analyzed according to the above conditions for relative density, strength, and grain size. Furthermore, sputtering was performed according to the above conditions and occurrence of arcing was investigated. The results are shown in Table 2.

TABLE 2

| | Evaluation for targets | | | | | | | | | |
|---|---|---|---|---|---|---|---|---|---|---|
| | | | Grain size | | | | | | | Sputtering |
| | | | | Max | Min | | Strength | | | Number of |
| | Density | | Average | grain size | grain size | Diff of | Max strength | Min strength | Diff of | arcing ×10\hat{ }3 |
| | Density | Relative | Grain size | Dmax | Dmin | grain size | Smax | Smin | strength | (Target life |
| | gcm⁻³ | density % | μm | μm | μm | Dmax/Dmin | MPa | MPa | Smax/Smin | 100%) |
| Ex 1 | 6.326 | 96.3 | 9.0 | 9.6 | 8.6 | 1.12 | 77 | 71 | 1.08 | 2.0 |
| Ex 2 | 6.324 | 96.3 | 8.7 | 8.8 | 8.4 | 1.05 | 81 | 72 | 1.13 | 1.7 |
| Ex 3 | 6.326 | 96.3 | 8.5 | 9.1 | 8.3 | 1.10 | 83 | 74 | 1.12 | 2.1 |
| Comp 1 | 6.329 | 96.4 | 8.5 | 9.5 | 7.8 | 1.22 | 90 | 68 | 1.32 | 5.4 |
| Ex 4 | 6.322 | 96.3 | 20.9 | 22.9 | 20.2 | 1.13 | 58 | 50 | 1.16 | 4.8 |
| Comp 2 | 6.321 | 96.2 | 20.2 | 23.6 | 17.7 | 1.33 | 64 | 45 | 1.42 | 8.5 |
| Comp 3 | 6.323 | 96.3 | 14.5 | 33.2 | 9.4 | 3.53 | 68 | 27 | 2.52 | 13.3 |
| Comp 4 | 6.322 | 96.3 | 12.8 | 19.3 | 9.5 | 2.03 | 71 | 33 | 2.15 | 9.8 |
| Comp 5 | 6.267 | 95.4 | 8.6 | 7.4 | 6.8 | 1.09 | 84 | 79 | 1.06 | 7.7 |

In the working examples 1-3 (holding by 900° C.), the targets had a small amount of deflection and had the small difference of grain size and strength. Furthermore, the targets had relative density more than certain level. Moreover, the numbers of occurrence of arcing for these targets were decreased blow certain level. Meanwhile, in the comparative example 1 (without holding at 900° C.), the amount of deflection was large, resulting in the large difference of grain size. Furthermore, the occurrence of arcing was more frequent.

The working example 4 and the comparative example 2 were the examples in which the temperature for sintering was higher to achieve larger crystal grain size. These examples show similar tendency to those of comparison between the working examples 1-3 and the comparative example 1.

In the comparative examples 3-4, holding at 900° C. was done as similar to the working example 1. However, because of the insufficient amount of grinding, a deteriorated layer remained in the surface, or the difference of the grain seize was large.

The comparative example 5 was the case where the thickness was 20 mm and the amount of grinding was larger to compensate for the thickness for the purpose of achieving the difference of grain size as similar to those of the working example 1. Although the difference of grain size was achieved to the similar degree of the working examples 1-3, the relative density was small. Thus, the number of occurrence of arcing was still high.

The term “or” described herein intends to include the case where either of listed elements is met, and the case where all of the listed elements are met. For example, “A or B” intends the case where A is met and B is not met, the case where B is met and A is not met, and the case where A is met and B is met.

The detailed embodiments of the present invention have been described. The above embodiments are merely example for the present invention, and the present invention is not limited to the above embodiments. For example, a technical feature disclosed in one embodiment may be applied to another embodiment. Furthermore, regarding to a method or process, the order of some steps may be switched from other steps. Also a further step may be inserted among certain two steps. The scope of the present invention is defined by the appended claim.

1. An IGZO sputtering target comprising In, Ga, Zn, and O,
wherein atom ratios for In, Ga, and Zn are:
30≤In/(In+Ga+Zn)≤0.36,
0.30≤Ga/(In+Ga+Zn)≤0.36 and
0.30≤Zn/(In+Ga+Zn)≤0.36,
wherein a relative density is at least 96%,
wherein average crystal grain size in surface of the sputtering target is 30.0 μm or less, and
wherein difference of the grain size in the surface of the sputtering target is 20% or less (1.0 Dmax/Dmin 1.2).

2. The IGZO sputtering target of claim 1,
wherein transverse intensity is from 40 to 100 MPa, and
wherein difference of the transverse intensity is 20% or less (1.0≤Smax/Smin≤1.2).

3. A method for preparing an IGZO sputtering target, comprising:
sintering a shaped body having elemental components according to claim 1 under 1300-1500° C. for 5-24 hours; and
grinding a sintered body;
the sintering including treating the shaped body under 800-1000° C. for 0.5-3 hours,
wherein an amount of the deflection for the sintered body after the sintering is 2.0 mm or less,
the grinding including additional grinding with an amount of 0.5 mm or more after removing deflection.

4. A method for preparing an IGZO sputtering target, comprising:
sintering a shaped body having elemental components according to claim 2 under 1300-1500° C. for 5-24 hours; and
grinding a sintered body;
the sintering including treating the shaped body under 800-1000° C. for 0.5-3 hours,
wherein an amount of the deflection for the sintered body after the sintering is 2.0 mm or less,
the grinding including additional grinding with an amount of 0.5 mm or more after removing deflection.
